(19) United States
(12) Patent Application Publication
(10) Pub. No.: US 2020/0144083 A1
(43) Pub. Date: May 7, 2020

(54) SUBSTRATE PROCESSING APPARATUS

(71) Applicant: SAMSUNG ELECTRONICS CO., LTD., Suwon-si (KR)

(72) Inventors: SEONGHOON YOON, Suwon-si (KR); Choong Kim, Suwon-si (KR); Seoung Hyun Seok, Suwon-si (KR); Hyeoncheol Jin, Suwon-si (KR)

(73) Assignee: SAMSUNG ELECTRONICS CO., LTD., Suwon-si (KR)

(21) Appl. No.: 16/670,573

(22) Filed: Oct. 31, 2019

(30) Foreign Application Priority Data
Nov. 1, 2018 (KR) 10-2018-0132797

(51) Int. Cl. H01L 21/67; H01L 21/683; H01J 37/32

(52) U.S. Cl. CPC H01L 21/67103; H01L 21/6833; H01J 2237/334; H01L 21/67069; H01L 21/67126; H01J 37/32724

(57) ABSTRACT

A substrate processing apparatus may include: a process chamber having a gate through which a substrate is transferred; a chuck provided in the process chamber to load the substrate; and a plurality of first protrusions and a plurality of second protrusions formed on the chuck and connected to a heater in the chuck. The first protrusions may be disposed in a region adjacent to the gate, with respect to a center of the chuck, and the second protrusions may be disposed in an opposite region distant from the gate, with respect to the center of the chuck. On the chuck, a sum of areas of top surfaces of the first protrusions per unit area of the chuck may be larger than a sum of areas of top surfaces of the second protrusions per unit area of the chuck, in a plan view of the chuck.

### CROSS-REFERENCE TO THE RELATED APPLICATIONS

This application claims priority from Korean Patent Application No. 10-2018-0132797, filed on Nov. 1, 2018, in the Korean Intellectual Property Office, the entire contents of which are hereby incorporated by reference.

### BACKGROUND

### 1. Field

Apparatuses and methods consistent with example embodiments of the inventive concept relate to a substrate processing apparatus, and more particularly, to a substrate processing apparatus configured to process a substrate using plasma.

### 2. Description of the Related Art

Semiconductor devices are manufactures by semiconductor fabrication processes, such as deposition, ion-implantation, photolithography, and etching processes. Some of the semiconductor fabrication processes are performed using plasma. As an integration density of the semiconductor device increases, feature sizes of patterns constituting semiconductor devices are decreasing and aspect ratios of the patterns are increasing. The decrease in feature size and the increase in aspect ratio of the pattern may lead to various technical issues in the semiconductor fabrication processes using the plasma. Accordingly, it is necessary to improve the semiconductor fabrication processes using the plasma.

### SUMMARY

Various embodiments of the inventive concept provide a substrate processing apparatus configured to improve uniformity in temperature of a substrate during substrate processing.

According to an embodiment, there is provided a substrate processing apparatus which may include: a process chamber having a gate through which a substrate is transferred; a chuck provided in the process chamber to load the substrate; and a plurality of first protrusions and a plurality of second protrusions formed on the chuck and connected to a heater in the chuck. The first protrusions may be disposed in a region adjacent to the gate, with respect to a center of the chuck, and the second protrusions may be disposed in an opposite region distant from the gate, with respect to the center of the chuck. On the chuck, a sum of areas of top surfaces of the first protrusions per unit area of the chuck may be larger than a sum of areas of top surfaces of the second protrusions per unit area of the chuck, in a plan view of the chuck.

According to an embodiment, there is provided a substrate processing apparatus which may include: a process chamber comprising a gate through which a substrate is provided; and a chuck comprising a body and protrusions which protrude from the body. The chuck may include a first region and a second region, which are opposite to each other with respect to a center of the body in a plan view of the chuck, and here, the first region may be disposed adjacent to the gate. A density of the protrusions in the first region may be greater than a density of the protrusions in the second region. A ratio of the number of the protrusions, which are provided in the first region, to an area of the first region may be greater than a ratio of the number of the protrusions, which are provided in the second region, to an area of the second region. The number of the protrusions per unit area of the chuck increases in a direction from the center of the body toward an edge of the body, in the plan view of the chuck.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view illustrating a substrate processing apparatus according to an embodiment.

FIG. 2 is a perspective view illustrating a chuck of a substrate processing apparatus according to an embodiment.

FIG. 3 is a plan view illustrating a chuck of a substrate processing apparatus according to an embodiment.

FIG. 4 is a sectional view illustrating a portion (e.g., portions of first and second regions) of a chuck according to an embodiment.

FIG. 5 is a plan view illustrating a chuck of a substrate processing apparatus according to an embodiment.

FIG. 6 is a sectional view illustrating a portion (e.g., portions of first and second regions) of a chuck according to an embodiment.

It should be noted that these figures are intended to illustrate the general characteristics of methods, structure and/or materials utilized in certain embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Various embodiments of the inventive concepts will now be described more fully with reference to the accompanying drawings, in which the embodiments are shown. The embodiments described herebelow are all exemplary, and thus, the inventive concept is not limited to these embodiments disclosed below and may be realized in various other forms.

It will be understood that when an element or layer is referred to as being “over,” “above,” “on,” “connected to” or “coupled to” another element or layer, it can be directly over, above, on, connected or coupled to the other element or layer or intervening elements or layers may be present. In contrast, when an element is referred to as being “directly over,” “directly above,” “directly on,” “directly connected to” or “directly coupled to” another element or layer, there are no intervening elements or layers present.

Spatially relative terms, such as “beneath,” “below,” “lower,” “over,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

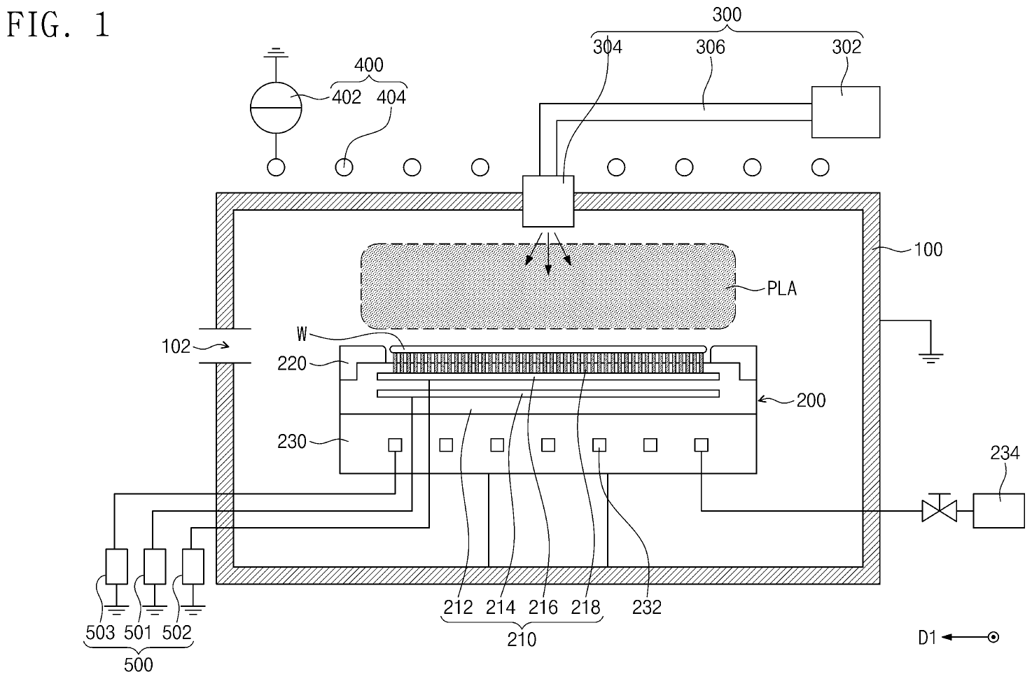

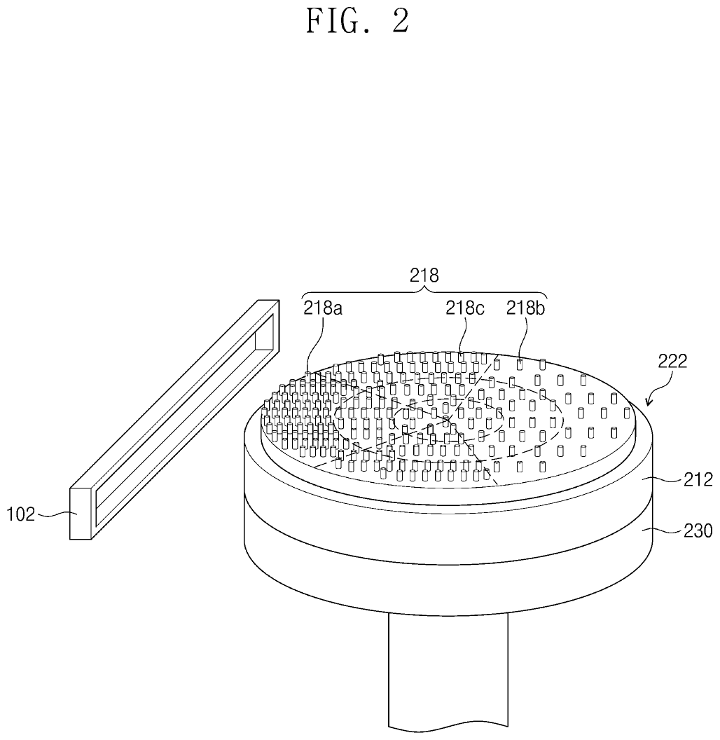

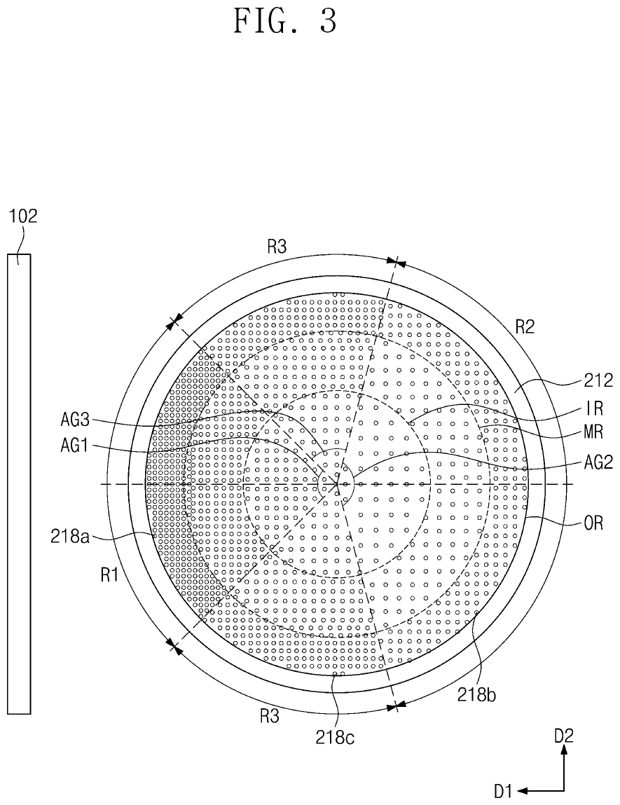

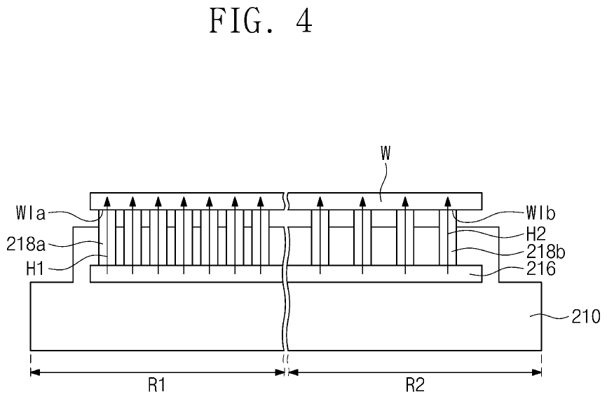

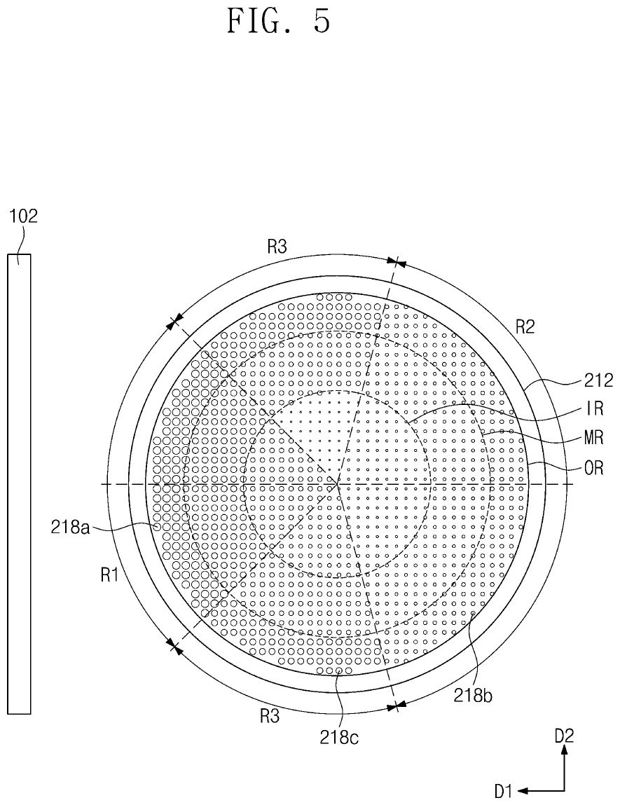

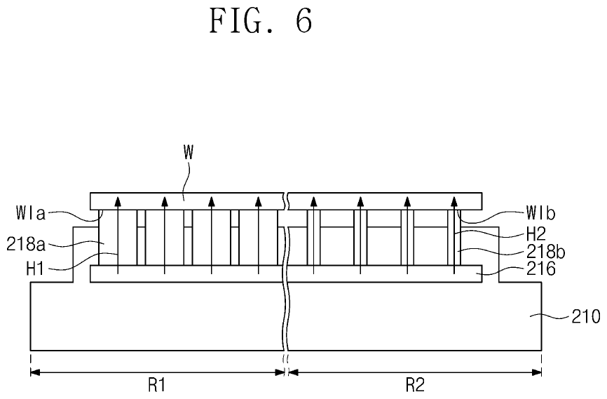

FIG. 1 is a sectional view illustrating a substrate processing apparatus according to an embodiment. FIG. 2 is a perspective view illustrating a chuck of a substrate processing apparatus according to an embodiment. FIG. 3 is a plan view illustrating a chuck of a substrate processing apparatus according to an embodiment. FIG. 4 is a sectional view illustrating a portion (e.g., portions of first and second regions) of a chuck according to an embodiment. FIG. 5 is a plan view illustrating a chuck of a substrate processing apparatus according to an embodiment. FIG. 6 is a sectional view illustrating a portion (e.g., portions of first and second regions) of a chuck according to an embodiment.

Referring to FIG. 1, a substrate processing apparatus may include a process chamber 100, a substrate support base 200, a gas supplier 300, a plasma generator 400, and a power supplier 500.

The process chamber 100 may provide therein a processing space which is used to perform a substrate processing process. For example, the process chamber 100 may be configured to have an internal processing space that is selectively isolated from the outside. The process chamber 100 may be formed of or include a metallic material. For example, the process chamber 100 may be formed of an aluminum-containing material. The process chamber 100 may further include an insulator or a heat shielding element. The insulator may prevent heat from being leaked to the outside of the process chamber 100, during the substrate processing process. For example, the insulator may be formed of or include a heat shielding material, such as ceramics. The process chamber 100 may be grounded. A gate 102 may be provided in a sidewall of the process chamber 100 in a first direction D1. The gate 102 may take a shape of a slit, allowing a substrate W to be transferred between the outside and inside regions of the process chamber 100. A shape of the gate 102 may not be limited to the slit, and different shapes may be formed for the same purpose according to embodiments. Although not shown, at least one exhausting hole may be provided at a bottom of the process chamber 100. The exhausting hole may be used to exhaust a by-product or a remnant gas, which is produced in a substrate processing process or is present in the internal space of the process chamber 100, to the outside of the process chamber 100. An internal pressure of the process chamber 100 may be reduced to a specific pressure by such an exhausting process.

The substrate support base 200 may be disposed in the process chamber 100. The substrate support base 200 may include a chuck 210. The chuck 210 may be disposed on the bottom surface of the process chamber 100. The substrate W may be loaded on a top surface of the chuck 210. A substrate processing process may be performed on the substrate W loaded on the chuck 210. The substrate W may be a semiconductor wafer (e.g., a silicon wafer). In an embodiment, the chuck 210 may be an electrostatic chuck, which is configured to support the substrate W using an electrostatic force. Alternatively, the substrate W loaded on the top surface of the chuck 210 may be supported by various methods (e.g., vacuum or mechanical clamping methods).

The chuck 210 may include a body 212 on which the substrate W is loaded, a DC electrode 214 and a heater 216, which are provided in the body 212, and a plurality of protrusions 218 supporting the substrate W. Hereinafter, the chuck 210 will be described in more detail with reference to FIGS. 1 and 2.

Referring to FIGS. 1 and 2, the body 212 may have a circular plate shape. The body 212 may have a diameter, which is greater than that of the substrate W loaded thereon. In a plan view, the body 212 may have a plurality of regions including a first region R1, a second region R2, and two third regions R3 between the first region R1 and the second region R2, as shown in FIG. 3. In the plan view, the first region R1 may be disposed in the first direction D1 from a center of the body 212 toward the gate 102. The second region R2 may be disposed in an opposite direction of the first direction D1 (i.e., in a direction away from the center of the body 212 and the gate 102). Each of the first region R1, the second region R2, and the third regions R3 may have a circular sectorial shape. As an example, the first region R1 may have a circular sectorial shape, whose vertex is located at the center of the body 212 and whose circumference is disposed in the first direction D1 relative to the center of the body 212. A central angle AG1 of a vertex of the first region R1 may be about 90°. The second region R2 may have a sectorial shape, whose vertex is located at the center of the body 212 and whose arc is disposed in the opposite direction of the first direction D1 relative to the center of the body 212. A central angle AG2 of a vertex of the second region R2 may be about 150°. Each of the third regions R3 may have a sectorial shape, whose vertex is located at the center of the body 212 and whose arc is disposed in a second direction D2 crossing the first direction D1 relative to the center of the body 212. A central angle AG3 of a vertex of each of the third regions R3 may be about 60°. However, the central angles AG1, AG2, and AG3 of the vertices of the first to third regions R1, R2, and R3 are not limited to this example. In certain embodiments, regions of the body 212 may be defined based on a distance from the center of the body 212. For example, as shown in FIG. 3, the body 212 may have an inner portion IR on the center of the body 212, an outer portion OR on the edge of the body 212, and a middle portion MR between the inner portion IR and the outer portion OR.

The DC electrode 214 may be disposed inside the body 212. The DC electrode 214 may be electrically connected to a DC power source 501. A current, which is applied to the DC electrode 214 from the DC power source 501, may produce an electrostatic force between the DC electrode 214 and the substrate W, and the substrate W may be fastened to the chuck 210 by the electrostatic force.

The heater 216 may be disposed inside the body 212. The heater 216 may be electrically connected to a heater power source 502. Heat may be produced in the heater 216 by a current applied from the heater power source 502. The heat may be transferred to the substrate W through the chuck 210. The heat supplied from the heater 216 may be used to maintain the substrate W to a specific temperature.

The protrusions 218 may be provided on the body 212. The protrusions 218 on the body 212 may support the substrate W. The protrusions 218 on the body 212 may be spaced apart from one another. Each of the protrusions 218 may have a circular pillar shape. A width of each protrusion 218, in the plan view, may range from 1 mm to 2 mm. Top surfaces of the protrusions 218 may be in contact with a bottom surface of the substrate W. The protrusions 218 may include first protrusions 218a provided on the first region R1, second protrusions 218b provided on the second region R2, and third protrusions 218c provided on the third regions R3. The protrusions 218 may be connected to the heater 216 through the body 212. The protrusions 218 may transfer the heat, which is provided from the heater 216, to the substrate W, and thus, the substrate W may be heated. The heat, which is transferred to the substrate W through the protrusions 218, may be dissipated through various leakage paths, during the substrate processing process.

According to an embodiment, the arrangement of the protrusions 218 may be designed in consideration of such heat leakage causes to improve uniformity of the heat provided to the substrate W or a process variation associated therewith. This will be described in more detail with reference to FIGS. 3 and 4.

One of the heat leakage causes may be the gate 102. The heat provided to the substrate W from the heater 216 may be leaked to the outside of the process chamber 100 through the gate 102 of the process chamber 100. In the case where the heat is uniformly provided to the substrate W, a temperature of a portion of the substrate W adjacent to the gate 102 (e.g., a portion of the substrate W on the first region R1) may be lower than that of another portion of the substrate W distant from the gate 102 (e.g., another portion of the substrate W on the second region R2), and in this case, the substrate processing process may suffer from a large process variation.

Referring to FIGS. 3 and 4, the smaller the distance from the gate 102, the higher a density of the protrusions 218. Here, the density of the protrusions 218 may be given by dividing the number of the protrusions 218 provided in a given region by an area of the region. For example, on the chuck 210, a density of the first protrusions 218a may be greater than a density of the third protrusions 218c, and the density of the third protrusions 218c may be greater than a density of the second protrusions 218b. A ratio of the number of the first protrusions 218a, which are provided on the first region R1, to an area of the first region R1 may be greater than a ratio of the number of the third protrusions 218c, which are provided on the third region R3, to an area of the third region R3. And, a ratio of the number of the third protrusions 218c, which are provided on the third region R3, to an area of the third region R3 may be greater than a ratio of the number of the second protrusions 218b, which are provided on the second region R2, to an area of the second region R2. Accordingly, in the plan view of the chuck 210, a sum of areas of top surfaces WIa of the first protrusions 218a per unit area of the chuck 210 may be greater than a sum of areas of top surface WIb of the second protrusions 218b per unit area of the chuck 210. In other words, an area of the first protrusions 218a, which are in contact with the substrate W, per unit area of the chuck 210 may be greater than an area of the second protrusions 218b, which are in contact with the substrate W, per unit area of the chuck 210, and an amount of heat H1, which is provided to the substrate W through the first region R1, may be greater than an amount of heat H2, which is provided to the substrate W through the second region R2. Although FIG. 3 illustrates an example, in which the protrusions 218 are arranged in a grid shape, the inventive concept is not limited to this example. The protrusions 218 may be arranged in various shapes (e.g., in a radial or honeycomb shape). In addition, the inventive concept is not limited to the specific number of the protrusions 218 shown in FIG. 3.

According to an embodiment, the protrusions 218 may be provided to have a high density, in a region adjacent to the gate 102, which is one of the heat leakage paths. In other words, the density of the protrusions 218 may be higher in the first region R1 adjacent to the gate 102 than in the second region R2, and a contact area between the protrusions 218 and the substrate W per unit area may be greater in the first region R1. Heat provided to a portion of the substrate W on the first region R1 may be greater than heat provided to another portion of the substrate W on the second region R2. Accordingly, the heat leaked through the gate 102 may be supplemented, and even when heat is leaked to the outside through the gate 102, the substrate W may be heated to substantially the same temperature throughout the first to third regions R1, R2, and R3. As a result, the temperature of the substrate W may be uniformly maintained throughout the entire region of the substrate W.

Another of the heat leakage causes may be a difference in position on the substrate W. Heat provided to the substrate W from the heater 216 may be leaked to an edge of the substrate W and an edge of the body 212. In the case where heat is uniformly provided on the substrate W, a portion of the substrate W on the outer portion OR may have a temperature lower than another portion of the substrate W on the inner portion IR, and in this case, the substrate processing process may suffer from a large thermal or process variation.

Referring further to FIG. 3, the greater a distance from the center of the body 212 of the chuck 210, the higher the density of the protrusions 218. On a straight line connecting the center of the body 212 with a point of the edge of the body 212, the number of the protrusions 218 per unit area of the chuck 210 may increase in a direction from the center of the body 212 toward the edge of the body 212. On the straight line, the density of the protrusions 218 may be highest in the outer portion OR and may be lowest in the inner portion IR. A contact area between the protrusions 218 and the substrate W per unit area of the chuck 210 may be greater in the outer portion OR than in the inner portion IR, and an amount of heat provided to the substrate W may be greater in the outer portion OR than in the inner portion IR.

In an embodiment, the protrusions 218 may be provided to have a high density at an edge of the body 212 on which an edge region of the substrate W, which is one of the heat leakage paths, is to be disposed. In other words, the density of the protrusions 218 may be higher in the outer portion OR than in the inner portion IR on the body 212, and a contact area between the protrusions 218 and the substrate W per unit area of the chuck 210 may be greater in the outer portion OR. Heat provided to a portion of the substrate W on the outer portion OR may be greater than heat provided to another portion of the substrate W on the inner portion IR. Accordingly, heat leaked to the edge of the substrate W may be supplemented, and even when the heat is leaked to the outside through the edge of the substrate W, the substrate W may be heated to substantially the same temperature throughout the inner portion IR, the middle portion MR, and the outer portion OR. As a result, the temperature of the substrate W may be uniformly maintained throughout the entire region of the substrate W.

According to the above-described embodiment of the inventive concept, the chuck 210 may be configured such that the density of the protrusions 218 is high in a region near the gate 102 and in the edge of the body 212. For example, in the first region R1 strongly affected by the gate 102, the first protrusions 218a may have the highest density in a region of the first region R1 overlapping the outer portion OR. In the second region R2 weakly affected by the gate 102, the second protrusions 218b may have the highest density in a region of the second region R2 overlapping the outer portion OR.

According to an embodiment, the density of the protrusions 218 may be determined in a region-dependent manner, in consideration of a difference in heat dissipation amount, which is caused by the presence of the gate 102 and the difference in position on the substrate W. Accordingly, it may be possible to uniformly maintain the temperature of the substrate W throughout the entire region of the substrate W and to reduce a process variation (e.g., a difference in etch rate between regions of the substrate W) in the substrate processing process performed on the substrate W.

In certain embodiments, the structure of the protrusions 218 may be designed to vary depending on the heat leakage causes to reduce a process variation. This will be described in more detail with reference to FIGS. 5 and 6.

The heat provided to the substrate W from the heater 216 may be leaked to the outside of the process chamber 100 through the gate 102 of the process chamber 100.

Referring to FIGS. 5 and 6, the protrusions 218 may be provided to have a uniform density on the body 212, but the smaller a distance to the gate 102, the greater an area of a top surface of each of the protrusions 218. For example, on the chuck 210, an area of the top surfaces WIa of the first protrusions 218a may be greater than an area of top surfaces of the third protrusions 218c, and the area of the top surfaces of the third protrusions 218c may be greater than the area of the top surfaces WIb of the second protrusions 218b. Accordingly, an area of the first protrusions 218a, which are in contact with the substrate W, per unit area of the chuck 210 may be greater than an area of the second protrusions 218b, which are in contact with the substrate W, per unit area of the chuck 210, and an amount of heat H1, which is provided to the substrate W through the first region R1 may be greater than an amount of heat H2, which is provided to the substrate W through the second region R2.

In an embodiment, the top surfaces of the protrusions 218 may have a greater area in a region adjacent to the gate 102, which is one of the heat leakage paths. In other words, a contact area between the protrusions 218 and the substrate W per unit area of the chuck 210 may be greater in the first region R1. Heat provided to a portion of the substrate W on the first region R1 may be greater than heat provided to another portion of the substrate W on the second region R2. Accordingly, the heat leaked through the gate 102 may be supplemented, and the substrate W may be heated to substantially the same temperature throughout the first to third regions R1, R2, and R3. As a result, the temperature of the substrate W may be uniformly maintained throughout the entire region of the substrate W. Widths of the first protrusions 218a range from 1.5 mm to 2.0 mm, and widths of the second protrusions 218b range from 1.0 mm to 1.5 mm.

Heat provided to the substrate W from the heater 216 may be leaked to an edge of the substrate W and an edge of the body 212.

Referring further to FIG. 5, the protrusions 218 may be provided to have a uniform density on the body 212, but the greater a distance from the center of the body 212 of the chuck 210, the greater an area of a top surface of each of the protrusions 218. On a straight line connecting the center of the body 212 with a point of the edge of the body 212, the area of the top surface of each of the protrusions 218 may increase in a direction from the center of the body 212 toward the edge of the body 212. For example, on the straight line, the area of the top surface of each of the protrusions 218 may be greatest in the outer portion OR and may be smallest in the inner portion IR. A contact area between the protrusions 218 and the substrate W per unit area of the chuck 210 may be larger in the outer portion OR than in the inner portion IR, and an amount of heat provided to the substrate W may be greater in the outer portion OR than in the inner portion IR.

In an embodiment, the protrusions 218 may be provided to have a greater top surface area at an edge of the body 212 on which the edge region of the substrate W, which is one of the heat leakage paths, is to be disposed. In other words, a contact area between the protrusions 218 and the substrate W per unit area of the chuck 210 may be greater in the outer portion OR. Heat provided to a portion of the substrate W on the outer portion OR may be greater than heat provided to another portion of the substrate W on the inner portion IR. Accordingly, heat leaked to the edge of the substrate W may be supplemented, and the substrate W may be heated to substantially the same temperature throughout the inner portion IR, the middle portion MR, and the outer portion OR. As a result, the temperature of the substrate W may be uniformly maintained throughout the entire region of the substrate W.

According to an embodiment, the shape of the protrusions 218 may be determined in a region-dependent manner, in consideration of a difference in heat dissipation amount, which is caused by the presence of the gate 102 and the difference in position on the substrate W. Accordingly, it may be possible to uniformly maintain the temperature of the substrate W throughout the entire region of the substrate W and to reduce a process variation (e.g., a difference in etch rate between regions of the substrate W) in the substrate processing process performed on the substrate W.

Referring back to FIG. 1, a frame 220 in a ring shape may be disposed on an edge of the chuck 210. The frame 220 may be adjacent to the edge of the loaded substrate W. The frame 220 may enclose the chuck 210. The frame 220 may protect the loaded substrate W and the chuck 210.

A lower electrode 230 may be disposed below the chuck 210. The lower electrode 230 may have a diameter larger than the substrate W. The lower electrode 230 may include a conductive material. The lower electrode 230 may be electrically connected to a first RF power source 503. The lower electrode 230 may serve as an RF electrode.

Coolant conduits 232 may be disposed in the lower electrode 230. The coolant conduits 232 may be connected to a coolant storage 234 through a coolant supply line. Coolant, which is supplied through the coolant supply line, may circulate along the coolant conduit 232 and may cool the lower electrode 230. The chuck 210 and the substrate W may also be cooled during the cooling of the lower electrode 230, and the temperature of the substrate W may be maintained to a specific temperature through this process. In certain embodiments, the coolant may be provided between the substrate W and the body 212, which are spaced apart from each other by the protrusions 218, to directly cool the substrate W.

The gas supplier 300 may supply a process gas into the process chamber 100. In an embodiment, the gas supplier 300 may include a gas storage 302 storing the process gas, a gas supply port 304 coupled to the process chamber 100, and a gas supply line 306 connecting the gas storage 302 to the gas supply port 304. The gas supply port 304 may be provided to penetrate a center region of a top portion of the process chamber 100. The gas supply port 304 may be or include a nozzle or a shower head, which is oriented toward the internal space of the process chamber 100. The gas supplier 300 may control a flow rate of the process gas supplied through the gas supply line 306.

The plasma generator 400 may generate plasma PLA from a process gas in the process chamber 100. In an embodiment, the plasma generator 400 may include a second RF power source 402 and an upper electrode 404 connected to the second RF power source 402. The second RF power source 402 may generate an RF power and may apply the RF power to the upper electrode 404. The upper electrode 404 may be, for example, a closed loop shape or a coil shape. The plasma PLA may be induced by the RF power applied to the upper electrode 404. The structure or shape of the plasma generator 400 may be variously changed as long as it can produce the plasma PLA. The plasma PLA generated by the plasma generator 400 may be used to perform a substrate processing process. In an embodiment, the substrate processing process may be or include an etching process.

The power supplier 500 may be provided outside the process chamber 100. The power supplier 500 may include the DC power source 501 electrically connected to the DC electrode 214, the heater power source 502 electrically connected to the heater 216, and the first RF power source 503 electrically connected to the lower electrode 230. The DC power source 501 may supply a DC power to the DC electrode 214. The heater power source 502 may supply an electric power to the heater 216. The first RF power source 503 may supply an RF power to the lower electrode 230.

According to an embodiment, a substrate processing apparatus may include protrusions, whose density is determined depending on a position of each region, in consideration of a difference in heat leakage caused by a gate and a difference in position on a substrate. Accordingly, it may be possible to maintain a substrate to a uniform temperature throughout the entire region of the substrate and to reduce a process variation (e.g., a difference in etch rate between regions of the substrate) in a substrate processing process performed on the substrate.

While example embodiments of the inventive concepts have been particularly shown and described, it will be understood by one of ordinary skill in the art that variations in form and detail may be made therein without departing from the spirit and scope of the attached claims.

What is claimed is:

1. A substrate processing apparatus, comprising:
a process chamber comprising a gate through which a substrate is transferred;
a chuck provided in the process chamber and configured to load the substrate thereon; and
a plurality of first protrusions and a plurality of second protrusions formed on the chuck and connected to a heater in the chuck,
wherein the first protrusions are disposed in a region adjacent to the gate, with respect to a center of the chuck,
wherein the second protrusions are disposed in an opposite region distant from the gate, with respect to the center of the chuck, and
wherein a sum of areas of top surfaces of the first protrusions per unit area of the chuck is greater than a sum of areas of top surfaces of the second protrusions per unit area of the chuck, in a plan view of the chuck.

2. The substrate processing apparatus of claim 1, wherein the first protrusions and the second protrusions have a same shape, and
wherein the number of the first protrusions per unit area of the chuck is greater than the number of the second protrusions per unit area of the chuck, in the plan view.

3. The substrate processing apparatus of claim 2, wherein the first protrusions and the second protrusions have a circular pillar shape, and
wherein a top surface of each of the first protrusions has a same area as a top surface of each of the second protrusions.

4. The substrate processing apparatus of claim 1, wherein a top surface of each of the first protrusions has an area greater than an area of a top surface of each of the second protrusions.

5. The substrate processing apparatus of claim 1, wherein, on a straight line connecting the center of the chuck to a point of an edge of the chuck, the number of the first protrusions per unit area of the chuck and the number of the second protrusions per unit area of the chuck increase in a direction from the center of the chuck toward the edge of the chuck, in the plan.

6. The substrate processing apparatus of claim 1, wherein an area of a top surface of each of the first protrusions and an area of a top surface of each of the second protrusions increase in a direction from the center of the chuck toward an edge of the chuck, in the plan view.

7. The substrate processing apparatus of claim 1, further comprising third protrusions disposed on the chuck,
wherein the third protrusions are disposed in a region between the regions, in which the first protrusions and the second protrusions are disposed.

8. The substrate processing apparatus of claim 7, wherein a sum of areas of top surfaces of the third protrusions per unit area of the chuck is greater than the sum of the areas of the top surfaces of the second protrusions per unit area of the chuck and is smaller than the sum of the areas of the top surfaces of the first protrusions of the chuck, in the plan view.

9. The substrate processing apparatus of claim 1, wherein the first protrusions are disposed on a first region of the chuck, and the second protrusions are disposed on a second region of the chuck, and
wherein the first region has a sectorial shape whose arc is located between the gate and its vertex, and the second region has a sectorial shape whose vertex is located between the gate and its arc, in the plan view.

10. The substrate processing apparatus of claim 1, wherein the first protrusions and the second protrusions are extended to penetrate the chuck and are connected to the heater in the chuck.

11. A substrate processing apparatus, comprising:
a process chamber comprising a gate through which a substrate is provided; and
a chuck comprising a body and protrusions which protrude from the body,
wherein the chuck comprises a first region and a second region, which are opposite to each other with respect to a center of the body in a plan view of the chuck,
wherein the first region is disposed adjacent to the gate,
wherein a density of the protrusions in the first region is greater than a density of the protrusions in the second region, and
wherein the number of the protrusions per unit area of the chuck increases in a direction from the center of the body toward an edge of the body, in the plan view.

12. The substrate processing apparatus of claim 11, wherein the first region has a sectorial shape whose arc is located between the gate and its vertex, and the second region has a sectorial shape whose vertex is located between the gate and its arc.

13. The substrate processing apparatus of claim 12, wherein a central angle of the first region is 90°, and a central angle of the second region is 150°.

14. The substrate processing apparatus of claim 12, wherein the chuck further comprises third regions provided between the first region and the second region, and
wherein each the third regions has a sectorial shape, whose vertex is positioned at or near a center of the chuck, in the plan view.

15. The substrate processing apparatus of claim 14, wherein a density of the protrusions on the third region is greater than the density of the protrusions on the second region and is smaller than the density of the protrusions on the first region.

16. The substrate processing apparatus of claim 12, wherein a central angle of the third region is 60°, in the plan view.

17. The substrate processing apparatus of claim 11, wherein a sum of areas of top surfaces of the protrusions per unit area of the chuck is greater in the first region than in the second region, in the plan view.

18. The substrate processing apparatus of claim 11, wherein the protrusions are extended to penetrate the body and are connected to a heater provided in the body.

19. The substrate processing apparatus of claim 11, wherein the protrusions take a circular pillar shape having widths ranging from 1 mm to 2 mm, in the plan view.

20. The substrate processing apparatus of claim 11, wherein an area of a top surface of each of the protrusions increases in a direction from the center of the body toward the edge of the body, in the plan view.
